(19) United States
(12) Patent Application Publication
(10) Pub. No.: US 2024/0034838 A1
(43) Pub. Date: Feb. 1, 2024

(54) POLYAMIC ACID RESIN AND POLYIMIDE FILM USING THE SAME

(71) Applicant: DOOSAN CORPORATION, Seoul (KR)

(72) Inventors: Kyungil AHN, Yongin-si (KR); Dongyoun KIM, Yongin-si (KR); Dayeong YU, Yongin-si (KR); Jaehyun SHIM, Yongin-si (KR)

(73) Assignee: DOOSAN CORPORATION, Seoul (KR)

(21) Appl. No.: 18/355,068

(22) Filed: Jul. 19, 2023

(30) Foreign Application Priority Data
Jul. 20, 2022 (KR) 10-2022-0089284

(51) Int. Cl. C08G 73/10; C08G 77/26; C08J 5/18

(52) U.S. Cl. CPC C08G 73/106; C08G 73/1007; C08G 73/1078; C08G 77/26; C08J 5/18

(57) ABSTRACT

A polyamic acid resin is copolymerized including: at least one diamine; at least one acid dianhydride; and polyhedral oligomeric silsesquioxane, and a transparent polyimide film is formed using the polyamic acid resin. The transparent polyimide film secures both excellent optical and mechanical properties through organic-inorganic hybrid formation, thus being applicable as a cover window for display devices.

### CROSS-REFERENCE TO RELATED APPLICATION

This application claims priority to Korean Patent Application No. 10-2022-0089284, filed on Jul. 20, 2022, and all the benefits accruing therefrom under 35 U.S.C. § 119, the content of which in its entirety is herein incorporated by reference.

### BACKGROUND

### 1. Field

Embodiments of the present invention relates to a polyamic acid resin and a transparent polyimide film using the same, and more particularly, to a polyamic acid resin including polyhedral oligomeric silsesquioxane (POSS) as a component of a polyamic acid composition to achieve organic-inorganic hybrid formation, thereby securing both excellent optical and mechanical properties to be used as a cover window for display devices, and to a transparent polyimide film using the same.

### 2. Description of the Related Art

A cover window for protecting a panel is applied to a surface of a display device such as a liquid crystal display (LCD) or an organic light emitting diode (OLED) display. As a material of the conventional cover window, a tempered glass having excellent characteristics such as flatness, heat resistance, chemical resistance, barrier performance against moisture or gas, a low coefficient of linear thermal expansion (CTE), and a high light transmittance has been largely used.

Recently, flexible displays such as curved displays or in-folding displays have been developed. In order to be applied to such a flexible display, the cover window should also have flexibility, but the conventional glass cover window is generally heavy and fragile and has poor flexibility, and thus is not suitable for the flexible display.

In order to solve the above problems, recently, cover windows using a plastic material having relatively free formability have been proposed. A cover window using a plastic material has advantages of being light-weighted, not being easily broken, and capable of implementing various designs.

Currently, polycarbonate, polyethylene terephthalate, polymethyl methacrylate, and the like having excellent transparency are largely used as plastic materials for cover windows. Although these materials have advantages of excellent transparency, their application is limited due to poor heat resistance with a glass transition temperature (Tg) of 150° C. or less, and poor chemical resistance and mechanical strength. In addition, the cover window is disposed at an outermost portion of the flexible display device, and when the above-described materials are applied and continuously exposed to external ultraviolet rays, yellowing occurs, which adversely affects the visibility of the display.

Currently, a polyimide resin is applied as a cover window material. Such a polyimide resin has a dark brown color due to the formation of a charge transfer complex (CTC) of pi-electrons in an imide chain, which makes it difficult to secure transparency, and in the case of a polyimide film including this, a surface thereof is easily scratched and a scratch resistance is very weak. In particular, a cover window made of the polyimide-based resin has the flexible properties of the polyimide material itself, but development to further improve the material properties and lifespan against fatigue failure caused by crack generation and propagation due to repeated stress and deformation is needs.

It is to be understood that this background of the technology section is intended to provide useful background for understanding the technology and as such disclosed herein, the technology background section may include ideas, concepts or recognitions that were not portion of what was known or appreciated by those skilled in the pertinent art prior to a corresponding effective filing date of subject matter disclosed herein.

### SUMMARY

Embodiments of the invention are directed to a novel polyimide film having excellent characteristics such as transparency, mechanical properties, and thermal properties through organic-inorganic hybrid formation to be applicable as a cover window.

According to an embodiment, a polyamic acid resin is copolymerized including: at least one diamine; at least one acid dianhydride; and polyhedral oligomeric silsesquioxane (POSS), wherein at least one of the diamine and the acid dianhydride includes an alicyclic compound.

In some embodiments, the polyamic acid resin may be applied to form a transparent polyimide film.

In some embodiments, the polyhedral oligomeric silsesquioxane may be included in an amount in a range from 0.1 to 15 percent by weight (wt %) with respect to the total 100 wt % of the solids of the polyamic acid resin.

In some embodiments, the polyhedral oligomeric silsesquioxane may be included in an amount in a range from 0.1 to 7 mole percent (mol %) with respect to 100 mol % of the diamine or the acid dianhydride.

In some embodiments, the alicyclic compound may include at least one of an alicyclic diamine and an alicyclic acid dianhydride, and the alicyclic compound may be included in an amount in a range from 10 to 100 mol % with respect to the total mol % of a sum of the diamine and the acid dianhydride.

In some embodiments, the alicyclic acid dianhydride may be included in an amount in a range from 10 to 100 mol % with respect to the total mol % of the acid dianhydride.

In some embodiments, the at least one acid dianhydride may further include one or more aromatic acid dianhydrides selected from: a fluorinated aromatic first acid dianhydride, a non-fluorinated aromatic second acid dianhydride, and a sulfone-based aromatic third acid dianhydride.

In some embodiments, the at least one diamine may include an aromatic diamine, an alicyclic diamine, or a combination of the aromatic diamine and the alicyclic diamine.

In some embodiments, the aromatic diamine and the alicyclic diamine may be included at a ratio in a range from 0 to 100:100 to 0 mol % with respect to the total 100 mol % of the diamine.

In some embodiments, the aromatic diamine may include one or more selected from: a fluorinated first diamine; a sulfone-based second diamine, a hydroxy-based third diamine, an ether-based fourth diamine, and a non-fluorine-based fifth diamine.

In some embodiments, a ratio (a/b) of the number of moles of the diamine (a) to the number of moles of the acid dianhydride (b) may be in a range from 0.7 to 1.3.

According to an embodiment, a transparent polyimide film is imidized including the above-described polyamic acid resin.

In some embodiments, with respect to a film thickness in a range from 30 to 100 μm, the transparent polyimide film may have a transmittance at a wavelength of 550 nm of 85% or more, and a yellow index according to ASTM E313-73 of 5 or less.

In some embodiments, the transparent polyimide film may have a Young's Modulus measured according to ASTM D882 in a range from 3 to 8 GPa, and a pencil hardness in a range from 2H to 5H.

In some embodiments, the transparent polyimide film may be used as a cover window for display devices.

According to one or more embodiments of the present invention, since polyhedral oligomeric silsesquioxane is used as one of reactants constituting a polyamic acid resin, organic/inorganic hybrid formation may be achieved, and thus characteristics such as high light transmittance, low yellow index and excellent mechanical properties may all be exhibited.

Accordingly, a transparent polyimide film using the above-described polyamic acid resin may be usefully applied as a cover window for display devices and flexible displays in the art such as flat panel display panels, as well as other IT products, electronic products, and home appliances known in the art.

The effect according to the present invention is not limited by the description exemplified above, and more various effects are included in the present specification.

### DETAILED DESCRIPTION

Hereinafter, the present invention will be described in detail. Embodiments of the present invention are provided to more completely explain the present invention to those of ordinary skill in the art, and the following examples may be modified in various other forms, and the scope of the present invention is not limited to the following examples. Herein, the same reference numerals refer to the same structures throughout this specification.

Unless otherwise defined, all terms (including technical and scientific terms) used herein may be used with the meaning commonly understood by those of ordinary skill in the art to which the present invention belongs. In addition, terms defined in a commonly used dictionary are not to be interpreted ideally or excessively unless clearly defined in particular.

In addition, throughout the specification, when a part “includes (comprises)” a certain component, this means that other components may be further included, rather than excluding other components, unless otherwise stated. In addition, throughout the specification, “on” or “above” means not only when it is located above or below the target part, but also includes the case where there is another part in the middle, and it does not necessarily mean that it is positioned above with respect to the direction of gravity. In the present specification, terms such as “first” and “second” do not indicate any order or importance, but are used to distinguish components from each other.

<Polyamic Acid Resin>

An embodiment of the present invention is a polyimide precursor [poly(amic acid), PAA] polymer for preparing a transparent polyimide film, specifically, a polyamic acid resin including polyhedral oligomeric silsesquioxane in a repeating unit.

More specifically, the polyamic acid resin may be copolymerized including: at least one diamine; at least one acid dianhydride; and polyhedral oligomeric silsesquioxane (POSS), where at least one of the diamine and the acid dianhydride includes an alicyclic compound.

That is, conventionally, silsesquioxane may have been added to improve the physical properties of polyimides, but these silsesquioxanes were mostly added in the form of fillers or applied in a mixed form as being added to polyamic acid resins or polyimide resins that have been polymerized.

On the other hand, in the present invention, polyhedral oligomeric silsesquioxane is used as one component of reactants of a composition for preparing polyamic acid. Specifically, silsesquioxane includes at least one amino group at a terminal thereof, and such an amino group participates in a reaction between diamine and acid dianhydride to further form an intramolecular chemical bond, thereby producing a polyamic acid resin having a higher molecular weight while being stronger and more rigid than a conventional polyamic acid having a linear structure. Since this polyamic acid resin is not decomposed by heat or light and is more stable against external impact, the optical properties, thermal properties, and mechanical properties (modulus, strength) of the transparent polyimide resin prepared using the polyamic acid resin may be significantly improved.

The polyhedral oligomeric silsesquioxane included in the polyamic acid resin according to the present invention includes a common silsesquioxane constitutional unit known in the art, for example, at least one constitutional unit of M unit, D unit, T unit and Q unit within a basic skeleton.

Here, “M unit” refers to a siloxane constitutional unit including a silicon atom and one oxygen atom adjacent thereto, for example, a siloxane unit represented by RSiO_{1/2}, and “D unit” refers to a siloxane constitutional unit (namely, a straight chain siloxane constitutional unit) including a silicon atom and two oxygen atoms adjacent thereto, for example, a siloxane unit represented by RSiO_{2/2}. In addition, “T unit” refers to a siloxane constitutional unit including a silicon atom and three oxygen atoms adjacent thereto, for example, a siloxane unit represented by RSiO_{3/2}, and “Q unit” refers to a siloxane constitutional unit including a silicon atom and four oxygen atoms adjacent thereto, for example, a siloxane unit represented by SiO_{4/2}.

In one specific example, the polyhedral oligomeric silsesquioxane may be represented by the following Chemical Formula 1:

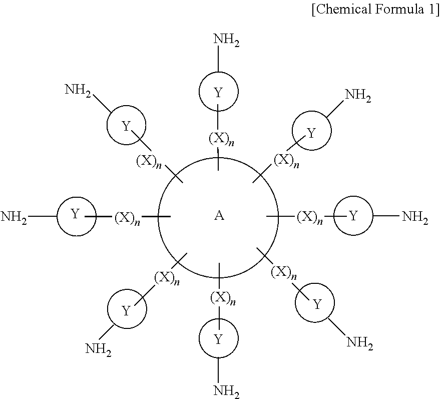

where in the above chemical formula,

A may be a polyhedral oligomeric silsesquioxane-derived group,

X may be the same as or different from each other, each independently being selected from: —CH₂—, —(CH₃)₂C—, —SO₂—, —(CF₃)₂C—, —CO—, and —CONH—,

n may be an integer of 0 or 1,

Y may be the same as or different from each other, each independently being selected from: a C₆ to C₃₀ aryl group and a C₃ to C₃₀ cycloalkyl group, or Y being bonded to form a condensed ring (e.g., a fused ring), and

the aryl group and the cycloalkyl group may each independently be substitutable with one or more substituents selected from: halogen, —CF₃, and —OH, and when the substituents are plural in number, they may be the same as or different from each other.

In a specific example, the polyhedral oligomeric silsesquioxane may be more specified into the following Chemical Formula 2:

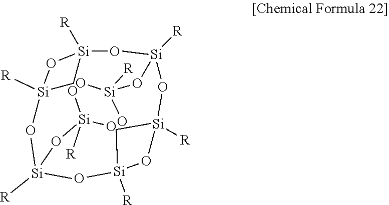

where in the above chemical formula,

the plurality of R may be the same as or different from each other, each independently being selected from: a C₆ to C₃₀ aryl group and a C₃ to C₃₀ cycloalkyl group substituted with an amine group, or R may be bonded to form a condensed ring, and

the aryl group and the cycloalkyl group may each independently be substitutable with one or more substituents selected from: halogen, —CF₃, —OH, and an amine group, and when the substituents are plural in number, they may be the same as or different from each other.

According to an embodiment of the present invention, if A, X, and Y of Chemical Formula 1 are more specified, they may be represented by Chemical Formula 3 below.

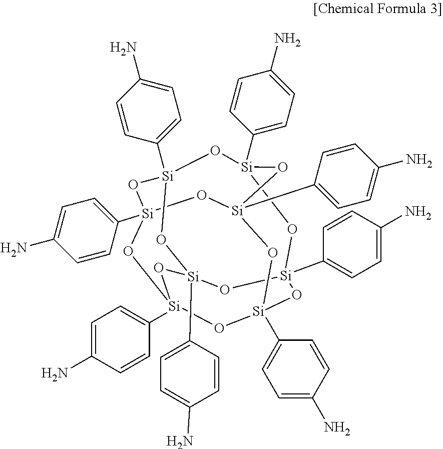 [SMILES: Nc1ccc([Si]23O[Si]4(c5ccc(N)cc5)O[Si]5(c6ccc(N)cc6)O[Si](c6ccc(N)cc6)(O2)O[Si]2(c6ccc(N)cc6)O[Si](c6ccc(N)cc6)(O3)O[Si](c3ccc(N)cc3)(O4)O[Si](c3ccc(N)cc3)(O5)O2)cc1]

The polyhedral oligomeric silsesquioxane according to the present invention includes a silsesquioxane constitutional unit (repeating unit, T unit) of [RSiO_{3/2}], and does not include a separate substituent such as an epoxy group. The T unit means a silsesquioxane constitutional unit including a silicon atom and three oxygen atoms adjacent thereto, and for example, may be derived from a condensate of a hydrolyzate of a trifunctional silane compound and/or a silane compound including three hydrolyzable groups. As an example, common alkyltrialkoxysilanes, aryltrialkoxysilanes, or mixtures thereof known in the art may be used. Non-limiting examples of applicable alkyltrialkoxysilane may include methyltrimethoxysilane, methyltriethoxysilane, methyltripropoxysilane, ethyltrimethoxysilane or ethyltriethoxysilane, propylethyltrimethoxysilane or mixtures thereof. Non-limiting examples of applicable aryltrialkoxysilane may include phenyltrimethoxysilane, phenyltriethoxysilane, naphthyltrimethoxysilane, naphthyltriethoxysilane, naphthyltripropoxysilane, or mixtures thereof.

As a specific example, the polyhedral oligomeric silsesquioxane may be a T3 body including 90 mole percent (mol %) or more, specifically in a range from 95 to 100 mol %, and more specifically in a range from 98 to 100 mol %, of a constitutional unit (T unit) represented by [RSiO_{3/2}].

In the present invention, a use amount of polyhedral oligomeric silsesquioxane is not particularly limited, and for example, it may be included in a range from 0.1 to 7 mol %, specifically in a range from 0.1 to 5 mol %, and preferably in a range from 0.5 to 5 mol %, with respect to 100 mol % of the corresponding diamine or acid dianhydride. When a content of polyhedral oligomeric silsesquioxane falls within the above range, a polyamic acid resin having a stronger chemical structure and high molecular weight may be formed. On the other hand, when the polyhedral oligomeric silsesquioxane exceeds the aforementioned content range, a certain amount or more of silsesquioxane may form multiple bonds by reaction with the polyamic acid resin, resulting in gelation (see Table 2 below).

The polyamic acid resin according to the present invention may include at least one diamine known in the art; and at least one acid dianhydride, where at least one of the diamine and the acid dianhydride is copolymerized including an alicyclic compound.

In the present invention, the alicyclic compound may include at least one of a common alicyclic diamine and an alicyclic acid dianhydride known in the art. The alicyclic diamine and the alicyclic acid dianhydride are not particularly limited as long as they include at least one alicyclic ring in a molecular structure, and may be, for example, alicyclic diamine or alicyclic acid dianhydride described below. Specifically, the alicyclic compound is an alicyclic acid dianhydride, and more specifically, it is preferable to use the alicyclic acid dianhydride represented by Chemical Formula 4 or 5. Such an alicyclic compound may be included in a range from 10 to 100 mol %, specifically, in a range from 50 to 90 mol %, with respect to the total mol % of a sum of the diamine and the acid dianhydride, for example, with respect to the total 200 mol % of a sum of 100 mol % of the diamine and 100 mol % of the acid dianhydride.

The diamine (a) component constituting the polyamic acid resin of the present invention is not limited as long as it is a compound having an intramolecular diamine structure, and common diamine compounds known in the art may be used without limitation. For example, an aromatic, alicyclic, or aliphatic compound having a diamine structure, or a combination thereof may be used.

In particular, in the present invention, considering optical properties of the polyimide film such as low reflectance, high transmittance, low Y.I. and the like, at least one type of alicyclic diamine may be used alone, or at least one type of aromatic diamine may be used, or the aromatic diamine and the alicyclic diamine may be used together.

Specific examples of the aforementioned aromatic diamine may include fluorine-based diamine having a fluorinated substituent, sulfone-based diamine, hydroxy-based diamine, ether-based diamine, and non-fluorine-based diamine, which may be used alone or in appropriate combination of one or more thereof. Accordingly, in the present invention, the diamine compound may include, for example, a fluorinated aromatic first diamine, a sulfone-based aromatic second diamine, a hydroxy-based aromatic third diamine, an ether-based aromatic fourth diamine, and a non-fluorine-based aromatic fifth diamine, which may be used alone or in appropriate combination of two or more thereof.

Non-limiting examples of applicable diamine monomer (a) may include 4,4′-oxydianiline (ODA), 2,2′-bis(trifluoromethyl)-4,4′-diaminobiphenyl (2,2′-TFDB), 2,2′-bis(trifluoromethyl)-4,3′-diaminobiphenyl, 2,2′-bis(trifluoromethyl)-5,5′-diaminobiphenyl), 2,2′-bis(trifluoromethyl)-4,4′-diaminophenyl ether (6-FODA), 2,2-bis(3-amino-4-hydroxyphenyl)hexafluoropropane, 2,2′-bis[4-(4-aminophenoxy)phenyl] hexafluoropropane (4BDAF), 2,2′-bis[4-(4-aminophenoxy)phenyl]propane (6HMDA), 4,4′-bis(3-aminophenoxy)diphenylsulfone (DBSDA), bis(4-aminophenyl)sulfone (4,4′-DDS), bis(3-aminophenyl)sulfone (3,3′-DDS), either alone or in combination of two or more thereof.

Considering high transparency, high glass transition temperature, and low yellow index of the polyimide film, the fluorinated first diamine may include 2,2′-bis(trifluoromethyl)-4,4′-diaminobiphenyl (2,2′-TFDB) and 1,4-bis(4-amino-2-trifluoromethylphenoxy)benzene (6-FAPB) which may induce linear polymerization. In addition, the sulfone-based second diamine may include bis(4-aminophenyl)sulfone (4,4′-DDS) or 3,3′-DDS. In addition, the hydroxy-based third diamine may include 2,2-bis(3-amino-4-hydroxyphenyl)hexafluoropropane (BIS-AP-AF). In addition, the ether-based fourth diamine may include 2,2′-bis(trifluoromethyl)-4,4′-diaminophenyl ether (6-FODA) or oxydianiline (ODA). In addition, the non-fluorine-based fifth diamine may include 2,2-bis(3-amino-4-methylphenyl)-hexafluoropropane (BIS-AT-AF), m-tolidine, or p-phenylenediamine (p-PDA).

In the diamine monomer (a) of the present invention, a content of the fluorinated aromatic first diamine, the sulfone-based aromatic second diamine, the hydroxy-based aromatic third diamine, the ether-based aromatic fourth diamine, the non-fluorine-based aromatic fifth diamine, the alicyclic diamine and the like is not particularly limited, but each may be included in an amount in a range from 0 to 100 mol %, specifically in a range from 10 to 90 mol %, and more specifically in a range from 20 to 80 mol %, with respect to the total 100 mol % of the diamine. However, a content of at least one of the above diamines may be to satisfy the total 100 mol % of the diamine.

Non-limiting examples of applicable alicyclic diamines may include 2,2-bis(3-amino-4-hydroxycyclohexyl)hexafluoropropane, 3,3′-dimethyl-4,4′-diaminodicyclohexylmethane (MACM), 4,4′-methylenebicyclohexylamine (PACM), 1,3-bis(aminomethyl)cyclohexane (1,3-BAC), 1,4-bis(aminomethyl)cyclohexane (1,4-BAC), cis-1,2-cyclohexanedimethanamine, trans-1,2-cyclohexanedimethanamine, 1,4-cyclohexyldiamine (CHDA), bis(4-aminocyclohexyl) ether, or mixtures thereof.

In the diamine monomer (a), a mixing ratio of the aromatic diamine and the alicyclic diamine may be in a range from 0 to 100:100 to 0 mol %, specifically in a range from 10 to 90:90 to 10 mol %, with respect to the total 100 mol % of the diamine.

The acid dianhydride (b) monomer constituting the polyamic acid resin of the present invention may include a common compound known in the art having an intramolecular acid dianhydride structure without limitation. For example, an aromatic, alicyclic, and aliphatic compound, or a combination thereof having an acid dianhydride structure may be used, and specifically, at least one type of alicyclic acid dianhydride may be used, or at least one type of aromatic acid dianhydride may be used, or the aromatic acid dianhydride and the alicyclic acid dianhydride may be used together.

The alicyclic acid dianhydride is not particularly limited as long as it is a compound having an acid dianhydride structure while having an alicyclic ring rather than an aromatic ring in the compound. Specifically, it is preferable to use an alicyclic acid dianhydride represented by the following Chemical Formula 4 or 5:

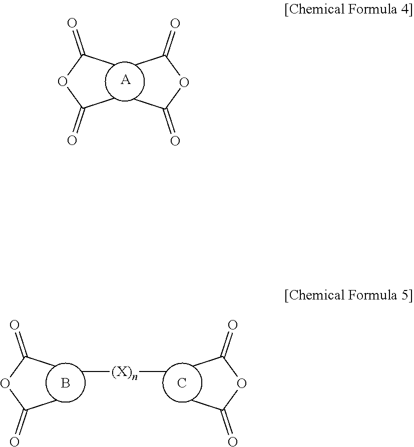

where in Chemical Formula 4 or 5,

A, B and C may be the same as or different from each other, each independently being a C₄ to C₂₀ alicyclic ring organyl group,

X may be selected from: —O—, —S—, —C(═O)—, —CH(OH)—, —S(═O)₂—, —(CH₂)ₚ— (where 1≤p≤10), —(CF₂)_{q}— (where 1≤q≤10), —(CH₃)₂C—, —(CF₃)₂C— and —C(═O)NH—, and

n may be an integer in a range from 0 to 2.

In a preferred example of Formula 4 or 5, A to C may be the same as or different from each other, each independently being a C₄ to C₂₀ alicyclic ring organyl group, X may be selected from: —(CH₂)—, —(CH₃)₂C—, —SO₂—, —(CF₃)₂C—, —CO—, and —CONH—, and n may be 0 or 1.

Non-limiting examples of applicable alicyclic acid dianhydrides may include cyclobutane tetracarboxylic dianhydride (CBDA), 1,2,3,4-cyclopentane tetracarboxylic dianhydride (CPDA), bicyclo[2,2,2]-7-octene-2,3,5,6-tetracarboxylic acid dianhydride (BCDA), 4-(2,5-dioxotetrahydrofuran-3-yl)-1,2,3,4-tetrahydronaphthalene-1,2-dicarboxylic anhydride (TDA), 1,1′-bicyclohexane-3,3′,4,4′-tetracarboxylic dianhydride (H-BPDA), 1,2,4,5-cyclohexane-tetracarboxylic dianhydride (H-PMDA), cyclopentanone bis-spironorbornane (cpODA), bicyclo[2.2.2]octane-2,3,5,6-tetracarboxylic 2,3:5,6-dianhydride (7CI,8CI) or a combination of one or more thereof.

A content of the alicyclic acid dianhydride is not particularly limited, and may be appropriately adjusted in consideration of mechanical properties and phase difference properties of the polyimide film. For example, a content of the alicyclic acid dianhydride may be in a range from 10 to 100 mol %, specifically in a range from 20 to 90 mol %, and more specifically in a range from 30 to 80 mol %, with respect to the total mol % of the acid dianhydride.

In addition, one specific example of the aromatic acid dianhydride may include, for example, a fluorinated aromatic first acid dianhydride, a non-fluorinated aromatic second acid dianhydride, and a sulfone-based aromatic third acid dianhydride, which may be used alone or in combination of at least two thereof.

The fluorinated first acid dianhydride monomer is not particularly limited as long as it is an aromatic acid dianhydride into which a fluorine substituent is introduced. Non-limiting examples of applicable fluorinated first acid dianhydride may include 2,2-bis(3,4-dicarboxyphenyl)hexafluoropropane dianhydride (6-FDA), 4-(trifluoromethyl)pyromellitic dianhydride (4-TFPMDA), and the like. These may be used alone or in combination of two or more thereof. Among the fluorinated acid dianhydrides, 6-FDA may be a suitable compound for transparency because it has a significantly high property of limiting formation of a charge transfer complex (CTC) between and within molecular chains.

The non-fluorinated second acid dianhydride monomer is not particularly limited as long as it is a non-fluorinated aromatic acid dianhydride into which a fluorine substituent is not introduced. Non-limiting examples of the applicable non-fluorinated second acid dianhydride monomer may include pyromellitic dianhydride (PMDA), 3,3′,4,4′-biphenyltetracarboxylic dianhydride (BPDA), benzophenone tetracarboxylic dianhydride (BTDA), oxydiphthalic dianhydride (ODPA), 4,4-(4,4-isopropylidenediphenoxy)bis(phthalic anhydride) (BPADA), (bis(3,4-dicarboxyphenyl)dimethylsilane dianhydride (SiDA), and the like. These may be used alone, or in combination of two or more thereof.

In addition, the sulfone-based third acid dianhydride monomer is not particularly limited as long as it is an acid dianhydride into which a sulfone group is introduced, for example, 3,3′,4,4′-diphenylsulfonetetracarboxylic dianhydride (DSDA), 4,4′-sulfonyldiphthalic anhydride (SO2DPA) and the like. These may be used alone, or in combination of two or more thereof.

In the acid dianhydride monomer (b) of the present invention, a content of the fluorinated aromatic first acid dianhydride, the non-fluorinated aromatic second acid dianhydride, the sulfone-based aromatic third acid dianhydride, and the like is not particularly limited. For example, they may be included in an amount in a range from 0 to 100 mol %, specifically in a range from 10 to 90 mol %, and more specifically in a range from 20 to 80 mol %, with respect to the total 100 mol % of the acid dianhydride. However, the content of at least one of the first acid dianhydride to the third acid dianhydride may be included to satisfy the total 100 mol % of the acid dianhydride.

In the acid dianhydride monomer (b) of the present invention, a mixing ratio of the aromatic acid dianhydride and the alicyclic acid dianhydride may be in a range from 0 to 90:10 to 100 mol %, specifically in a range from 90 to 10:10 to 90 mol % ratio, and more specifically in a range from 80 to 10:20 to 90 mol %, with respect to the total 100 mol % of the acid dianhydride.

In a polyamic acid preparation composition constituting the polyamic acid resin of the present invention, a ratio (a/b) of the number of moles of the diamine component (a) to the number of moles of the acid dianhydride component (b) may be in a range from 0.7 to 1.3, preferably in a range from 0.8 to 1.2, and more preferably in a range from 0.9 to 1.1.

In addition, the polyamic acid preparation composition constituting the polyamic acid resin of the present invention may use, without limitation, an organic solvent known in the art as a solvent for the solution polymerization of the above-described monomers. Examples of the applicable solvents may include at least one polar solvent selected from: m-cresol, N-methyl-2-pyrrolidone (NMP), dimethylformamide (DMF), dimethylacetamide (DMAc), dimethyl sulfoxide (DMSO), acetone, diethyl acetate, and dimethyl phthalate (DMP). In addition, a low-boiling point solution such as tetrahydrofuran (THF) and chloroform, or a solvent such as γ-butyrolactone may be used. In such a case, a content of the solvent (a first solvent for polymerization) is not particularly limited, but in order to obtain an appropriate molecular weight and viscosity of the polyamic acid composition (the polyamic acid solution), it may be preferably in a range from 50 to 95 percent by weight (wt %), and more preferably in a range from 70 to 90 wt %, with respect to the total weight of the polyamic acid composition.

In the present invention, the above-described dianhydride, diamine and polyhedral oligomeric silsesquioxane may be added to a solvent and then reacted to prepare a transparent polyamic acid composition. In one example, the polyhedral oligomeric silsesquioxane of Chemical Formula 1, at least one diamine component, and at least one dianhydride are included, where an equivalent ratio of the diamine (a) and the dianhydride (b) is about 1:1 to form a transparent polyamic acid composition so as to improve glass transition temperature and yellow index.

A composition of the polyamic acid composition is not particularly limited, and for example, may include 2.5 to 25.0 wt % of dianhydride, 2.5 to 25.0 wt % of diamine, and a residual amount of an organic solvent satisfying 100 wt % of the composition, with respect to the total 100 wt % of the polyamic acid composition, where the polyhedral oligomeric silsesquioxane may be included in an amount in a range from 0.1 to 15 wt % with respect to the total 100 wt % of the solid content of the polyamic acid. For example, a content of the organic solvent may be in a range from 70 to 90 wt %.

The polyamic acid composition constituted as described above may have a viscosity in a range from about 1,000 to 200,000 cps, preferably in a range from about 5,000 to 50,000 cps. When the viscosity of the polyamic acid composition falls within the above range, thickness control during coating of the polyamic acid composition may be easy, and a coating surface may be uniformly formed.

If necessary, the polyamic acid composition may include a small amount of at least one additive such as a plasticizer, an antioxidant, a flame retardant, a dispersant, a viscosity modifier, a leveling agent, and the like within a range that does not significantly impair the purpose and effect of the present invention.

<Transparent Polyimide Film>

Another embodiment of the present invention is a transparent polyimide film prepared by imidizing the above-described polyamic acid resin, specifically, a transparent polyimide film which is imidized by ring-closing dehydrating, at a high temperature, a polyamic acid resin solution formed by solution polymerization of a polyamic acid composition including polyhedral oligomeric silsesquioxane.

Such a transparent polyimide film may be provided in a display device, and more specifically, may be used as a cover window of a flexible display. Here, the cover window refers to a film disposed at an outermost portion of a flexible display device to protect the display device. The cover window may be a window film alone or a film in which an adhesive layer and a window coating layer are formed on a separate substrate film made of an optically transparent resin.

In order for the transparent polyimide film according to the present invention to be used as a cover window for a mobile communication terminal or a tablet PC, it is preferable to have both excellent optical and mechanical properties such as high transparency and light transmittance.

Specifically, the polyamic acid resin and the polyimide film of the present invention may include at least one diamine; at least one acid dianhydride; and polyhedral oligomeric silsesquioxane, while including a repeating unit obtained by including at least one alicyclic diamine or alicyclic acid dianhydride, where the polyhedral oligomeric silsesquioxane included in the repeating unit may be included in an amount in a range from 0.1 to 15 wt % with respect to the total 100 wt % of the solids of the polyamic acid resin. When a predetermined alicyclic repeating unit obtained from such an alicyclic diamine/acid dianhydride is included, excellent visibility and mechanical properties may be secured, and at the same time, excellent mechanical properties such as high strength and high hardness may be significantly enhanced to be optimized due to a silsesquioxane moiety included in the repeating unit.

In a specific example, the polyimide film may have a light transmittance at a wavelength of 550 nm of 85% or more, specifically 89% or more, and more specifically in a range from 90% to 99% at a thickness of 30 to 100 μm. In addition, a yellow index (yellowness index, Y.I.) according to the ASTM E313 standard may be 5 or less, specifically 4.7 or less, and more specifically 4.5 or less. The optical properties are measured based on a thickness of the polyimide film in a range from 30 to 100 μm, specifically in a range from 30 to 80 μm, and specifically 40±5 μm.

In another specific example, the polyimide film may have a Young's Modulus in a range from 3 to 8 GPa, and specifically in a range from 3 to 6 GPa. In terms of exhibiting both mechanical hardness and excellent flexibility, it may be in a range from 4 to 6 GPa. Here, the Young's modulus is one of modulus types, and represents a relational ratio when a material is subject to a load within an elastic limit, and specifically refers to a value measured according to the ASTM D882. When the modulus is smaller than the aforementioned value, it may be difficult to exhibit sufficient hardness, and when the modulus is greater than the aforementioned value, the flexibility may be lowered and the foldability may be degraded.

In another specific example, the polyimide film may have an average coefficient of linear thermal expansion (CTE) of 100 ppm/° C. or less, specifically 70 ppm/° C. or less, and more specifically in a range from 30 to 65 ppm/° C. measured at a thickness of 30 to 100 μm and at a temperature in a range from 50 to 250° C.

The polyimide resin film according to the present invention may be prepared according to a conventional method known in the art, for example, it may be prepared by coating (casting) the above-described polyamic acid composition on a substrate such as a glass substrate, and then inducing an imide ring-closure reaction (imidization) for 0.5 to 8 hours while gradually raising the temperature in a range from 30 to 350° C.

In such a case, a common coating method known in the art may be used without limitation as the coating method, and for example, it may be implemented by at least one selected from: spin coating, dip coating, solvent casting, slot die coating, and spray coating. The polyamic acid composition may be coated at least once or more so that a thickness of the colorless and transparent polyimide resin layer is several hundred nm to several tens of μm.

In the polyimide film preparing method according to the present invention, an imidization method applied in the imidization step through casting of the polymerized polyamic acid on a support may include a thermal imidization method, a chemical imidization method, or a combination of the thermal imidization method and the chemical imidization method.

The thermal imidization method is a method of obtaining a polyimide film by casting a polyamic acid composition (polyamic acid solution) on a support and heating it for 1 to 10 hours while gradually raising the temperature in a temperature range from 30 to 400° C.

The chemical imidization method is a method of adding a dehydrating agent represented by an acid anhydride such as acetic anhydride, and an imidization catalyst represented by amines such as isoquinoline, β-picoline, and pyridine to the polyamic acid composition. When the thermal imidization method is used in combination with the chemical imidization method, the heating conditions of the polyamic acid composition may vary according to the type of the polyamic acid composition, the thickness of the polyimide film to be prepared, and the like.

More specifically, when the thermal imidization method and the chemical imidization method are used in combination, after a dehydrating agent and an imidization catalyst are added to the polyamic acid composition and cast on a support, it is partially cured and dried by heating at a temperature in a range from 80 to 300° C., preferably in a range from 150 to 250° C., to activate the dehydrating agent and the imidization catalyst, and thus a polyimide film may be obtained.

The polyimide resin thus formed in such a manner is a polymer material including an imide ring, and has excellent characteristics such as heat resistance, chemical resistance, abrasion resistance and electrical properties based on the chemical stability of the imide ring. The polyimide resin may be in the form of a random copolymer or a block copolymer. A thickness of the polyimide film is not particularly limited, and may be appropriately adjusted according to the field to which it is applied. For example, it may be in a range from 10 to 150 μm, preferably in a range from 30 to 100 μm.

The polyamic acid resin, the polyimide film, and variants thereof of the present invention prepared as described above may be usefully applied in various fields requiring excellent optical properties such as high transmittance and yellow index and excellent mechanical properties such as high modulus. In particular, it may be applied as a cover window of a display device to prevent surface abrasion due to high hardness and strength, and it is possible to provide excellent visibility and high reliability to the flexible display device. Such a display device may be applicable to display devices known in the art without limitation, in particular, for example, an in-folding or out-folding type foldable display.

In the present invention, a display device refers to a flexible display device or a non-flexible display device that displays an image, and may include a flat panel display (FPD) device as well as a curved display device, a foldable display device, a flexible display device, a foldable mobile phone, a smart phone, a mobile communication terminal, or a tablet PC. Specifically, the display device may include a liquid crystal display, an electrophoretic display, an organic light emitting display, an inorganic electroluminescence (EL) display, a field emission display, a surface-conduction electron-emitter display, a plasma display, a cathode ray tube display, an electronic paper, or the like. For example, it may be a flat panel display panel such as LCD, PDP, or OLED. However, the polyimide film of the present invention may be applied to a common display device known in the art, not limited to the afore-mentioned use, and may be utilized as a substrate or a protective film for other flexible displays.

A specific example of the display device including the above-described polyimide film may include a display unit, a polarizing plate, a touch screen panel, a cover window, and a protective film, where the cover window may include a polyimide film according to an embodiment of the present invention. Here, each component constituting the display device is not particularly limited, and may include conventional components known in the art.

Hereinafter, the present invention will be described in more detail through specific examples. The following examples are only examples to help the understanding of the present invention, and the scope of the present invention is not limited thereto.

### Examples 1 to 16. Polyimide Film Preparation

Polyamic acid compositions were prepared using a composition including diamine, acid dianhydride, and octa(aminophenyl) silsesquioxane (OAPS) of Chemical Formula 3 as shown in Table 1 below.

After spin-coating the polyamic acid composition on a glass for LCD, it was dried and a ring-closure imidization reaction was carried out, while gradually raising the temperature stepwise in a convection oven in a nitrogen atmosphere for 30 minutes at 80° C., 30 minutes at 150° C., 1 hour at 200° C., and 1 hour at 300° C. Accordingly, a polyimide film having a film thickness of 40 μm and an imidization ratio of 85% or more was prepared. Thereafter, the polyimide film was peeled off the glass and taken.

TABLE 1

| | Diamine (mol %) | | Acid dianhydride (mol %) | | |
|---|---|---|---|---|---|
| | First | Second | First | Second | OAPS |
| Classification | monomer | monomer | monomer | monomer | (mol %) |
| Ex. 1 | TFDB(100) | — | CBDA(70) | BPDA(30) | 0.1 |
| Ex. 2 | TFDB(100) | — | CBDA(70) | BPDA(30) | 1 |
| Ex. 3 | TFDB(100) | — | CBDA(70) | BPDA(30) | 2 |
| Ex. 4 | TFDB(100) | — | CBDA(70) | BPDA(30) | 5 |
| Ex. 5 | TFDB(100) | — | HBPDA(70) | DSDA(30) | 0.1 |
| Ex. 6 | TFDB(100) | — | HBPDA(70) | DSDA(30) | 1 |
| Ex. 7 | TFDB(100) | — | HBPDA(70) | DSDA(30) | 2 |
| Ex. 8 | TFDB(100) | — | HBPDA(70) | DSDA(30) | 5 |
| Ex. 9 | 6FODA(100) | — | CBDA(70) | BPADA(30) | 0.1 |
| Ex. 10 | 6FODA(100) | — | CBDA(70) | BPADA(30) | 1 |
| Ex. 11 | 6FODA(100) | — | CBDA(70) | BPADA(30) | 2 |
| Ex. 12 | 6FODA(100) | — | CBDA(70) | BPADA(30) | 5 |
| Ex. 13 | TFDB(80) | CHDA(20) | BPDA(70) | DSDA(30) | 0.1 |
| Ex. 14 | TFDB(80) | CHDA(20) | BPDA(70) | DSDA(30) | 1 |
| Ex. 15 | TFDB(80) | CHDA(20) | BPDA(70) | DSDA(30) | 2 |
| Ex. 16 | TFDB(80) | CHDA(20) | BPDA(70) | DSDA(30) | 5 |
| Comp. Ex. 1 | TFDB(100) | — | CBDA(70) | BPDA(30) | 0 |
| Comp. Ex. 2 | TFDB(100) | — | CBDA(70) | BPDA(30) | 10 |
| Comp. Ex. 3 | TFDB(100) | — | HBPDA(70) | DSDA(30) | 0 |
| Comp. Ex. 4 | TFDB(100) | — | HBPDA(70) | DSDA(30) | 10 |
| Comp. Ex. 5 | 6FODA(100) | — | CBDA(70) | BPADA(30) | 0 |
| Comp. Ex. 6 | 6FODA(100) | — | CBDA(70) | BPADA(30) | 10 |
| Comp. Ex. 7 | TFDB(80) | CHDA(20) | BPDA(70) | DSDA(30) | 0 |
| Comp. Ex. 8 | TFDB(80) | CHDA(20) | BPDA(70) | DSDA(30) | 7.5 |
| Comp. Ex. 9 | TFDB(100) | — | CBDA(70) | BPDA(30) | 5 |

### Comparative Examples 1 to 8. Polyimide Film Preparation

Polyimide films of Comparative Examples 1 to 8 were prepared, respectively, in the same manner as in Examples 1 to 16, except for using the composition shown in Table 1 above.

### Comparative Example 9. Polyimide Film Preparation

A polyamic acid resin was prepared by polymerizing diamine and acid dianhydride shown in Table 1, and then octa(aminophenyl) silsesquioxane (OAPS) of Chemical Formula 3 was added to the prepared polyamic acid resin, followed by stirring for 12 hours to prepare a polyamic acid composition.

After spin-coating the polyamic acid composition on a glass for LCD, it was dried and a ring-closure imidization reaction was carried out, while gradually raising the temperature stepwise in a convection oven in a nitrogen atmosphere for 30 minutes at 80° C., 30 minutes at 150° C., 1 hour at 200° C., and 1 hour at 300° C. Accordingly, a polyimide film having a film thickness of 40 μm and an imidization ratio of 85% or more was prepared. Thereafter, the polyimide film was peeled off the glass and taken.

### Experimental Example. Physical Property Evaluation

The physical properties of the polyimide resin films prepared in Examples 1 to 16 and Comparative Examples 1 to 9 were evaluated in the following manner, and the results are shown in Table 2 below. In such a case, each physical property in Table 2 is based on a thickness of 50 μm of the polyimide film.

<Method for Evaluating Physical Properties>

1) Measurement of Light Transmittance

Measurements were carried out using a UV-Vis NIR Spectrophotometer (Shimadzu, model name: uv-3150) at a wavelength of 550 nm.

2) Yellow Index Measurement

A yellow index at 550 nm was measured according to the ASTM E313-73 standard using a spectrophotometer (Konica Minolta, model name: CM-3700d).

3) Thickness Measurement

A thickness of the film was measured using a thickness meter (Mitutoyo, model name: 293-140).

4) Modulus Measurement

A modulus (GPa) was measured according to the ASTM D882 standard using UTM (Instron, model name: 5942).

5) Measurement of Pencil Hardness

A pencil hardness was measured at a 750 g load using a pencil hardness tester under the ISO 15184 standard.

TABLE 2

| | Modulus | Transmittance | | Pencil |
|---|---|---|---|---|
| Classification | (GPa) | (%) | YI | hardness |
| Ex. 1 | 5.6 | 90.1 | 1.7 | 3H |
| Ex. 2 | 6.1 | 89.2 | 2 | 4H |
| Ex. 3 | 6.8 | 88.6 | 3.2 | 5H |
| Ex. 4 | 7.1 | 87.1 | 4.5 | 5H |
| Ex. 5 | 4.7 | 89.2 | 3.2 | 2H |
| Ex. 6 | 4.9 | 88.7 | 3.6 | 2H |
| Ex. 7 | 5.4 | 88.2 | 3.9 | 3H |
| Ex. 8 | 6.2 | 87.7 | 4.4 | 4H |
| Ex. 9 | 4.3 | 90.3 | 3.2 | 2H |
| Ex. 10 | 4.7 | 89.4 | 3.6 | 2H |
| Ex. 11 | 5 | 88.7 | 3.9 | 3H |
| Ex. 12 | 5.5 | 88.2 | 4.3 | 3H |
| Ex. 13 | 4.9 | 88.7 | 3.5 | 2H |
| Ex. 14 | 5.3 | 88.3 | 4.1 | 3H |
| Ex. 15 | 5.6 | 87.9 | 4.4 | 3H |
| Ex. 16 | 5.9 | 87 | 4.9 | 4H |
| Comp. Ex. 1 | 5.3 | 90.2 | 1.5 | 2H |
| Comp. Ex. 2 | Gelation | | | |
| Comp. Ex. 3 | 4.5 | 89.4 | 2.9 | 1H |
| Comp. Ex. 4 | Gelation | | | |
| Comp. Ex. 5 | 4.1 | 90.3 | 3 | F |
| Comp. Ex. 6 | Gelation | | | |
| Comp. Ex. 7 | 4.7 | 88.7 | 3.2 | 1H |
| Comp. Ex. 8 | Partial gelation | | | |
| Comp. Ex. 9 | 5.8 | 86.9 | 5.1 | 3H |

As shown in Table 2, it was appreciated that the polyimide film of the present invention including polyhedral oligomeric silsesquioxane had superior optical and mechanical properties compared to Comparative Examples. In particular, the modulus property tends to increase as the content of polyhedral oligomeric silsesquioxane increases. On the other hand, in the case of Comparative Examples 2, 4, 6 and 8 in which the content of polyhedral oligomeric silsesquioxane is 10 mol % and 7.5 mol %, it was appreciated that excess polyhedral oligomeric silsesquioxane reacted with the polyamic acid resin to cause gelation, and a film itself was not formed.

In the case of the polyimide film of Comparative Example 9 which was prepared by producing a polyamic acid resin first and then adding polyhedral oligomeric silsesquioxane, it showed poor optical and mechanical properties compared to Example 4 of the present application having the same composition. Accordingly, it was appreciated that when polyhedral oligomeric silsesquioxane is used as one of reactants of the polyamic acid resin, it is possible to produce a more strong and rigid polyamic acid resin having a high molecular weight, thereby significantly improving optical and mechanical properties of the polyimide resin.

Accordingly, it was confirmed that the polyimide film of the present invention may be usefully applicable as a cover window of display devices.

While the present invention has been illustrated and described with reference to the embodiments thereof, it will be apparent to those of ordinary skill in the art that various changes in form and detail may be made thereto without departing from the spirit and scope according to an embodiment.

What is claimed is:

1. A polyamic acid resin, copolymerized comprising:
at least one diamine;
at least one acid dianhydride; and
polyhedral oligomeric silsesquioxane (POSS),
wherein at least one of the diamine and the acid dianhydride comprises an alicyclic compound.

2. The polyamic acid resin of claim 1, for forming a transparent polyimide film.

3. The polyamic acid resin of claim 1, wherein the polyhedral oligomeric silsesquioxane is comprised in an amount in a range from 0.1 to 15 percent by weight (wt %) with respect to the total 100 wt % of the solids of the polyamic acid resin.

4. The polyamic acid resin of claim 1, wherein the polyhedral oligomeric silsesquioxane is represented by the following Chemical Formula 1: 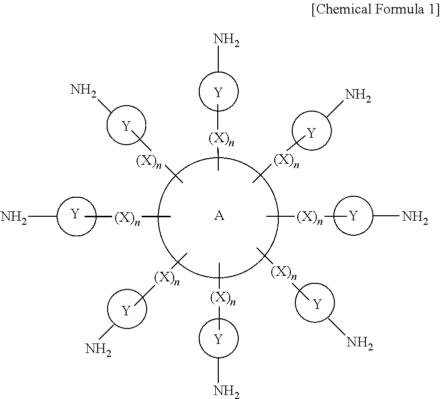
wherein in the above chemical formula,
A is a polyhedral oligomeric silsesquioxane-derived group
X are the same as or different from each other, each independently being selected from: —CH₂—, —(CH₃)₂C—, —SO₂—, —(CF₃)₂C—, —CO—, and —CONH—,
Y are the same as or different from each other, each independently being selected from: a C₆ to C₃₀ aryl group and a C₃ to C₃₀ cycloalkyl group, or bonded to each other form a condensed ring,
the aryl group and the cycloalkyl group are each independently substitutable with one or more substituents selected from: halogen, —CF₃, and —OH, and when the substituents are plural in number, they are the same as or different from each other, and
n is an integer of 0 or 1.

5. The polyamic acid resin of claim 1, wherein the polyhedral oligomeric silsesquioxane is comprised in an amount in a range from 0.1 to 7 mole percent (mol %) with respect to 100 mol % of the diamine or the acid dianhydride.

6. The polyamic acid resin of claim 1, wherein the alicyclic compound comprises at least one of an alicyclic diamine and an alicyclic acid dianhydride, and
the alicyclic compound is comprised in an amount in a range from 10 to 100 mol % with respect to the total mol % of a sum of the diamine and the acid dianhydride.

7. The polyamic acid resin of claim 6, wherein the alicyclic acid dianhydride is a compound represented by the following Chemical Formula 4 or 5, 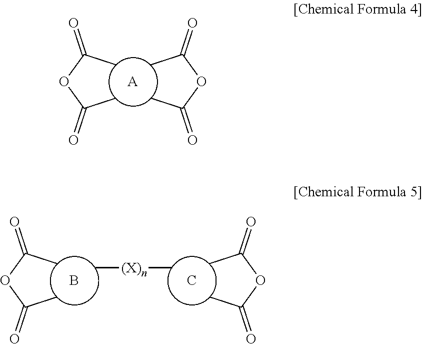
wherein in Chemical Formula 4 or 5,
A, B and C are the same as or different from each other, each independently being a C₄ to C₂₀ alicyclic ring organyl group,
X is selected from: —O—, —S—, —C(═O)—, —CH(OH)—, —S(═O)₂—, —(CH₂)ₚ— (where 1≤p≤10), —(CF₂)_{q}— (where 1≤q≤10), —(CH₃)₂C—, —(CF₃)₂C— and —C(═O)NH—, and
n is an integer in a range from 0 to 2.

8. The polyamic acid resin of claim 6, wherein the alicyclic acid dianhydride is comprised in an amount in a range from 10 to 100 mol % with respect to the total mol % of the acid dianhydride.

9. The polyamic acid resin of claim 1, wherein the at least one acid dianhydride further comprises one or more aromatic acid dianhydrides selected from: a fluorinated aromatic first acid dianhydride, a non-fluorinated aromatic second acid dianhydride, and a sulfone-based aromatic third acid dianhydride.

10. The polyamic acid resin of claim 1, wherein the at least one diamine comprises an aromatic diamine, an alicyclic diamine, or a combination of the aromatic diamine and the alicyclic diamine.

11. The polyamic acid resin of claim 10, wherein the aromatic diamine and the alicyclic diamine are comprised at a ratio in a range from 0 to 100:100 to 0 mol % with respect to the total 100 mol % of the diamine.

12. The polyamic acid resin of claim 11, wherein the aromatic diamine comprises one or more selected from: a fluorinated first diamine; a sulfone-based second diamine, a hydroxy-based third diamine, an ether-based fourth diamine, and a non-fluorine-based fifth diamine.

13. The polyamic acid resin of claim 1, wherein a ratio (a/b) of the number of moles of the diamine (a) to the number of moles of the acid dianhydride (b) is in a range from 0.7 to 1.3.

14. A transparent polyimide film imidized comprising the polyamic acid resin according to claim 1,
wherein the polyamic acid resin is copolymerized comprising:
at least one diamine;
at least one acid dianhydride; and
polyhedral oligomeric silsesquioxane,
wherein at least one of the diamine and the acid dianhydride comprises an alicyclic compound.

15. The transparent polyimide film of claim 14, wherein the polyhedral oligomeric silsesquioxane is comprised in an amount in a range from 0.1 to 15 percent by weight (wt %) with respect to the total 100 wt % of the solids of the polyamic acid resin.

16. The transparent polyimide film of claim 14, wherein the polyhedral oligomeric silsesquioxane is represented by the following Chemical Formula 1: 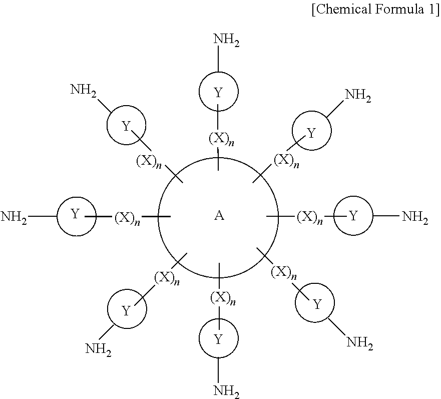
wherein in the above chemical formula,
A is a polyhedral oligomeric silsesquioxane-derived group
X are the same as or different from each other, each independently being selected from: —CH₂—, —(CH₃)₂C—, —SO₂—, —(CF₃)₂C—, —CO—, and —CONH—,
Y are the same as or different from each other, each independently being selected from: a C₆ to C₃₀ aryl group and a C₃ to C₃₀ cycloalkyl group, or bonded to each other form a condensed ring,
the aryl group and the cycloalkyl group are each independently substitutable with one or more substituents selected from: halogen, —CF₃, and —OH, and when the substituents are plural in number, they are the same as or different from each other, and
n is an integer of 0 or 1.

17. The transparent polyimide film of claim 14, wherein the polyhedral oligomeric silsesquioxane is comprised in an amount in a range from 0.1 to 7 mole percent (mol %) with respect to 100 mol % of the diamine or the acid dianhydride.

18. The transparent polyimide film of claim 14, wherein with respect to a film thickness in a range from 30 to 100 μm,
a transmittance at a wavelength of 550 nm is 85% or more, and
a yellow index is 5 or less.

19. The transparent polyimide film of claim 14, wherein a Young's Modulus measured according to ASTM D882 is in a range from 3 to 8 GPa, and
a pencil hardness is in a range from 2H to 5H.

20. The transparent polyimide film of claim 14, used as a cover window for display devices.
